(19) United States
(12) Patent Application Publication
(10) Pub. No.: US 2016/0324015 A1
(43) Pub. Date: Nov. 3, 2016

(54) CONTROLLER FOR POWER CONVERTER

(71) Applicant: AISIN AW CO., LTD., Anjo-shi (JP)

(72) Inventors: Keita MUTSUURA, Miyoshi (JP); Tatsuya KONDO, Okazaki (JP); Masakazu SATO, Anjo (JP)

(73) Assignee: AISIN AW CO., LTD., Anjo-shi, Aichi-ken (JP)

(21) Appl. No.: 15/108,361

(22) PCT Filed: Jan. 19, 2015
(86) PCT No.: PCT/JP2015/051261

§ 371 Date: Jun. 27, 2016

(30) Foreign Application Priority Data
Feb. 13, 2014 (JP) 2014-025203

(51) Int. Cl. H05K 5/00; H05K 7/14

(52) U.S. Cl. CPC H05K 5/0017; H05K 7/1417

(57) ABSTRACT

A controller for a power converter that includes a multilayer board; a microcomputer that is implemented in a first area on one surface of the multilayer board; a power IC that is implemented in a second area on the other surface of the multilayer board; and a wiring that is formed in the multilayer board, and connects the microcomputer and the power IC to each other, wherein the second area is configured to be included in the first area when viewed in a normal direction of the multilayer board, and the multilayer board includes a portion of a ground potential in the second area when viewed in the normal direction of the multilayer board.

### BACKGROUND

The present disclosure relates to a controller for a power converter.

A configuration in which a microcomputer (hereinafter simply referred to as “microcomputer”) and a power supply circuit are disposed at different positions on the same surface of a printed circuit board for a display unit has been known (for example, refer to JP-A-2011-096871).

### SUMMARY

However, in the above configuration disclosed in JP-A-2011-096871, since the microcomputer and the power supply circuit are disposed at the different positions on the same surface of the board, it is difficult to downsize the board.

Therefore, an exemplary aspect of the present disclosure provides a controller for a power converter capable of downsizing a board.

According to an exemplary aspect of the present disclosure, a controller for a power converter includes: a multilayer board; a microcomputer that is implemented in a first area on one surface of the multilayer board; a power IC that is implemented in a second area on the other surface of the multilayer board; and a wiring that is formed in the multilayer board, and connects the microcomputer and the power IC to each other, wherein the second area is configured to be included in the first area when viewed in a normal direction of the multilayer board, and the multilayer board includes a portion of a ground potential in the second area when viewed in the normal direction of the multilayer board.

According to the present disclosure, the controller for a power converter capable of downsizing the board can be obtained.

### BRIEF DESCRIPTION OF THE DRAWINGS

FIGS. 1A and 1B are diagrams illustrating an example of a board in a controller for a power converter.

FIG. 2 is a cross-sectional view of the board along a line C-C in FIG. 1A.

FIG. 3 is a diagram schematically illustrating an example of the controller for a power converter in an implemented state.

### DETAILED DESCRIPTION OF EMBODIMENTS

Hereinafter, respective embodiments will be described with reference to the accompanying drawings in detail.

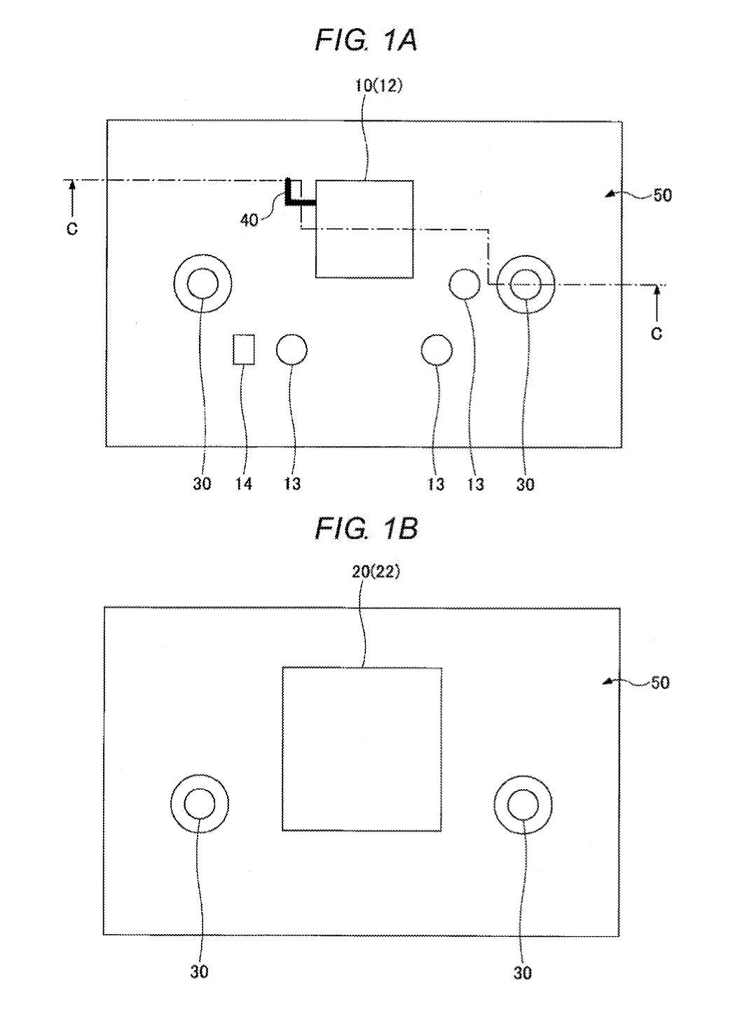

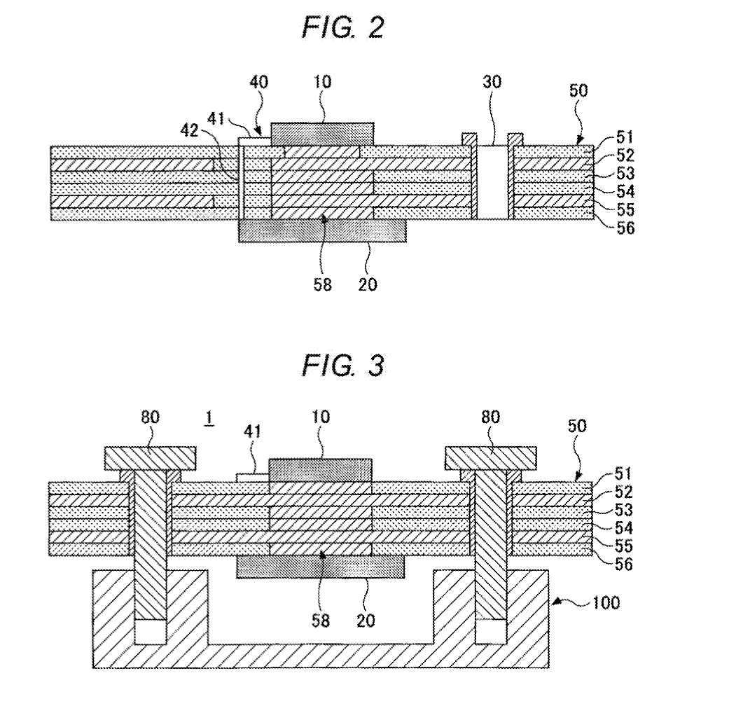

FIGS. 1A and 1B are diagrams schematically illustrating an example of a board 50 of a controller 1 for a power converter, in which FIG. 1A is a diagram illustrating one surface (A-plane in this example) of the board 50, and FIG. 1B is a diagram illustrating the other surface (B-plane in this example) of the board 50. FIG. 2 is a cross-sectional view of the board 50 along a line C-C of FIG. 1A.

The power converter may be configured by, for example, an inverter or a DC-DC converter. For example, the inverter is intended for driving a motor, and the motor may be configured by a traveling motor used for a hybrid vehicle or an electric vehicle.

A power IC (integrated circuit) 10 for a microcomputer is implemented in a power IC area 12 on the A-plane of the board 50. Electronic components (inductors 13, a capacitor 14, etc.) used for a microcomputer power supply circuit are disposed on the A-plane of the board 50. The power IC 10 may be configured by a switching power IC for driving a switching element.

A microcomputer 20 is implemented in a microcomputer installation area 22 of a B-plane of the board 50. The microcomputer 20 includes a CPU and a memory. The microcomputer 20 receives a power supply from the power IC 10. In other words, the microcomputer 20 operates due to an electric power from the power IC 10. The microcomputer 20 has a function of controlling, for example, an inverter, and an inverter control program is stored in the memory (for example, ROM) of the microcomputer 20 along with the inverter control.

The microcomputer installation area 22 is configured to internally have (include) the power IC area 12 when viewed from a normal direction of the board 50. In other words, the microcomputer installation area 22 overlaps with the power IC area 12 over the entire power IC area 12 when viewed from the normal direction of the board 50.

Bolt insertion holes 30 are provided in the board 50. The bolt insertion holes 30 represent a form of through-holes. A conductor part having a ground potential in use is provided in each of the bolt insertion holes 30. The bolt insertion holes 30 may be made of a metal collar, or may be formed by through-holes plated with a conductor.

Preferably, as illustrated in FIGS. 1A and 1B, the bolt insertion holes 30 are provided on both sides of the microcomputer 20 (in other words, both sides of the microcomputer installation area 22).

A wiring 40 for electrically connecting the microcomputer 20 and the power IC 10 to each other is disposed in the board 50. As illustrated in FIG. 2, the wiring 40 includes a pattern part 41 on the board 50, and a through-hole 42. In other words, since the microcomputer 20 and the power IC 10 are implemented on respective different surfaces of the board 50, the microcomputer 20 and the power IC 10 are electrically connected to each other through the through-hole 42. The through-hole 42 is electrically insulated from the conductor part (including a solid pattern) of the ground potential in the board 50.

As illustrated in FIG. 2, the board 50 is configured by a multilayer board. In an example illustrated in FIG. 2, the board is configured by a board of six layers having a first layer 51 to a sixth layer 56, but the number of layers is arbitrary. The first layer 51 to the sixth layer 56 may include a signal transmission layer, a power supply layer, and a ground connection layer. Meanwhile, in FIG. 2, hatched parts represent conductor portions in the respective layers of the board 50.

The board 50 includes a conductor portion (hereinafter referred to as “ground potential part”) 58 having a ground potential in use. The ground potential part 58 is formed to overlap with the power IC area 12 when viewed in the normal direction of the board 50. The ground potential part 58 is formed in the respective layers of the board 50. Meanwhile, in the example illustrated in FIG. 2, the ground potential part 58 in each of the second layer 52 and the fifth layer 55 is formed in a solid pattern (for example, the same solid pattern). A range in which the ground potential part 58 is formed is arbitrary, and preferably determined so as to sufficiently exert a radiation function and a shield function of electromagnetic waves by the ground potential part 58. In the example illustrated in FIG. 2, the ground potential part in each of the other layers 51, 52, 53, and 56 overlaps with the power IC area 12 when viewed in the normal direction of the board 50, but is formed to be smaller than the microcomputer installation area 22. However, some or all of the ground potential parts in the other layers 51, 52, 53, and 56 may be formed in the same area as the microcomputer installation area 22, or formed to be larger than the microcomputer installation area 22 when viewed in the normal direction of the board 50.

According to the board 50 of the controller 1 for a power converter illustrated in FIGS. 1A, 1B, and 2, since the microcomputer 20 and the power IC 10 are implemented on both surfaces of the board 50, the board 50 can be downsized more than a configuration in which those components are implemented on the same surface of the board 50.

Incidentally, in recent years, in order to realize a reduction in the size of the printed circuit board and a higher performance, a switching power IC is used as the microcomputer power supply circuit, and a microcomputer including a high-performance CPU is used as the microcomputer. In this case, there is a need to sufficiently take measures against noise and heat generation due to switching in the power IC. In addition, there is a need to sufficiently take measures against EMC (electro-magnetic compatibility) and crosstalk in the microcomputer.

In this regard, according to the board 50 of the controller 1 for a power converter illustrated in FIGS. 1A, 1B, and 2, the microcomputer 20 and the power IC 10 are disposed to overlap with each other when viewed in the normal direction of the board 50. As a result, the common ground potential part 58 can be provided between the microcomputer 20 and the power IC 10 when viewed in the normal direction of the board 50, and the respective measures for the microcomputer 20 and the power IC 10 are commonly (efficiently) realized by using a small area in the board 50. Specifically, the ground potential part 58 can function as a radiation pad for transmitting a heat of the power IC 10 to an external, and can also function as an electromagnetic wave shield for shielding radiation noise from the microcomputer 20. In addition, the ground potential part 58 can function as a radiation pad for transmitting a heat of the microcomputer 20 to the external.

According to the board 50 of the controller 1 for a power converter illustrated in FIGS. 1A, 1B, and 2, since the ground potential part 58 is provided in each layer of the board 50, a heat capacity can be efficiently enhanced with the use of the small area in the board 50. As a result, a heat radiation property can be efficiently enhanced.

According to the board 50 of the controller 1 for a power converter illustrated in FIGS. 1A, 1B, and 2, since the microcomputer 20 and the power IC 10 are disposed to overlap with each other in the normal direction of the board 50, the microcomputer 20 and the power IC 10 can be connected to each other in a short distance. In other words, a distance of the wiring 40 can be reduced. The same is applied to wirings for power supply to peripheral equipments (not shown) that may be provided in the periphery of the microcomputer 20.

According to the board 50 of the controller 1 for a power converter illustrated in FIGS. 1A, 1B, and 2, since the microcomputer 20 and the power IC 10 are disposed to overlap with each other when viewed in the normal direction of the board 50, the bolt insertion holes 30 can be disposed on both sides of the microcomputer 20 and the power IC 10. The bolt insertion holes 30 serve as fixed places of the board 50 as will be described later. Therefore, since both sides of the microcomputer 20 and the power IC 10 are fixed, the transmission of vibration to the microcomputer 20 and the power IC 10 can be reduced. The inductors 13 and the capacitor 14, which are weight components, can be disposed in the vicinity of the bolt insertion holes 30, and the vibration of those weight components can be suppressed.

FIG. 3 is a cross-sectional view schematically illustrating an example of the controller 1 for a power converter in an implemented state. FIG. 3 corresponds to a cross-sectional view taken along a cross-section passing through the bolt insertion holes 30 on both sides of the microcomputer 20 and the power IC 10 in the board 50.

The board 50 is fixed to a case 100 having a ground potential. The board 50 is fixed to the case 100 by bolts 80 that pass through the respective bolt insertion holes 30, and are fastened to the case 100. The bolts 80 are electrically connected to the ground potential part 58 of the board 50 through the conductor part of the bolt insertion holes 30. As a result, the ground potential part 58 is electrically connected to the case 100, and has the ground potential.

Preferably, the board 50 is fixed to the case 100 in a state where the microcomputer 20 faces the case 100. As a result, the case 100 can function as an electromagnetic shield for shielding the radiation noise from the microcomputer 20. As a result, the radiation noise from the microcomputer 20 can be shielded by both of the case 100 and the ground potential part 58, and the shield performance can be enhanced. The board 50 may be fixed to the case 100 in a state where the power IC 10 faces the case 100.

The respective embodiments have been described in detail above, but the present disclosure is not limited to the specific embodiments, and can be variously modified or changed within the scopes of the claims. All or some of the components in the embodiments described above can be combined together.

For example, in the embodiments described above, the board 50 is fixed to the case 100 by the two bolts 80, but may be fixed to the case 100 by a larger number of bolts 80.

In the embodiments described above, the ground potential part 58 is formed in each layer of the board 50, but may be formed in only a part of the layers in the board 50. Similarly, in this case, it is desirable that the ground potential part 58 is formed to sufficiently achieve the radiation function and the shield function of the electromagnetic wave.

The present international application claims priority based on Japanese Patent Application No. 2014-025203 filed on Feb. 13, 2014, and the entire contents thereof are incorporated herein by reference.

Meanwhile, the following exemplary disclosure is made in the above embodiments.

(1) A controller (1) for a power converter, including: a multilayer board (50); a microcomputer (20) that is implemented in a first area (22) on one surface of the multilayer board (50); a power IC (10) that is implemented in a second area (12) on the other surface of the multilayer board (50); and a wiring (40) that is formed in the multilayer board (50), and connects the microcomputer (20) and the power IC (10) to each other, in which the second area (12) is configured to be included in the first area (22) when viewed in a normal direction of the multilayer board (50), and the multilayer board (50) includes a portion (58) of a ground potential in the second area (12) when viewed in the normal direction of the multilayer board (50).

According to the configuration described in the item (1), the microcomputer (20) and the power IC (10) are disposed to overlap with each other when viewed in the normal direction of the multilayer board (50). As a result, the respective radiation measures for the microcomputer (20) and the power IC (10) can be commonly (efficiently) realized with the use of the small area in the multilayer board (50). Specifically, the portion (58) of the ground potential can function as the radiation pad for transmitting the heat of the power IC (10) to the external, and can also function as the electromagnetic wave shield for shielding radiation noise from the microcomputer (20). In addition, the portion (58) of the ground potential can function as the radiation pad for transmitting the heat of the microcomputer (20) to the external.

(2) The controller (1) for a power converter according to the item (1), in which the portion (58) of the ground potential is formed on each layer of the multilayer board (50).

According to the configuration described in the item (2), the heat capacity can be efficiently enhanced with the use of the small area in the multilayer board (50), and the heat radiation property can be efficiently enhanced.

(3) The controller (1) for a power converter according to the item (1) or (2), further including a case (100) to which the multilayer board (50) is fixed, and which has the ground potential, and bolts (80) for fixing the multilayer board (50) to the case (100), in which the multilayer board (50) has insertion holes (30) for the bolts (80) on both sides of the first area (22), and the portion (58) of the ground potential is electrically connected to the bolts (80).

According to the configuration described in the item (3), since both sides of the microcomputer (20) and the power IC (10) are fixed, the transmission of vibration to the microcomputer (20) and the power IC (10) can be reduced. Even when an inductor or the like, which is a weight component, is disposed in the vicinity of the insertion holes (30), the vibration of the weight component can be suppressed.

(4) The controller (1) for a power converter according to the item (3), in which the multilayer board (50) is fixed to the case (100) in a state where the one surface is directed toward the case (100) side.

According to the configuration described in the item (4), the radiation noise from the microcomputer (20) can be shielded by both of the case (100) and the portion (58) of the ground potential, and the shield performance can be enhanced.

1-4. (canceled)

5. A controller for a power converter comprising:
a multilayer board;
a microcomputer that is implemented in a first area on one surface of the multilayer board;
a power IC that is implemented in a second area on the other surface of the multilayer board; and
a wiring that is formed in the multilayer board, and connects the microcomputer and the power IC to each other, wherein
the second area is configured to be included in the first area when viewed in a normal direction of the multilayer board, and the multilayer board includes a portion of a ground potential in the second area when viewed in the normal direction of the multilayer board.

6. The controller for a power converter according to claim 5, wherein the portion of the ground potential is formed on each layer of the multilayer board.

7. The controller for a power converter according to claim 5, further comprising:
a case to which the multilayer board is fixed, and which has the ground potential; and
bolts for fixing the multilayer board to the case, wherein:
the multilayer board has insertion holes for the bolts on both sides of the first area, and
the portion of the ground potential is electrically connected to the bolts.

8. The controller for a power converter according to claim 6, further comprising:
a case to which the multilayer board is fixed, and which has the ground potential; and
bolts for fixing the multilayer board to the case, wherein:
the multilayer board has insertion holes for the bolts on both sides of the first area, and
the portion of the ground potential is electrically connected to the bolts.

9. The controller for a power converter according to claim 7, wherein the multilayer board is fixed to the case in a state where the one surface is directed toward the case side.

10. The controller for a power converter according to claim 8, wherein the multilayer board is fixed to the case in a state where the one surface is directed toward the case side.
